(19) United States
(12) Patent Application Publication
(10) Pub. No.: US 2008/0024970 A1
(43) Pub. Date: Jan. 31, 2008

(54) Laptop

(75) Inventor: Jack Lee, Taipei City (TW)

Correspondence Address: BIRCH STEWART KOLASCH & BIRCH, PO BOX 747, FALLS CHURCH, VA, 22040-0747, US

(73) Assignee: Dialogue Technology Corp.

(21) Appl. No.: 11/822,364

(22) Filed: Jul. 5, 2007

Related U.S. Application Data
(63) Continuation-in-part of application No. 11/493,636, filed on Jul. 27, 2006, now abandoned.

(51) Int. Cl. H05K 5/00

(52) U.S. Cl. 361/683

(57) ABSTRACT

A laptop has a wireless module set in a base or elsewhere and an antenna set in a display or elsewhere. A transmission wire is distributed both in the base and the display to connect the wireless module and the antenna for providing the function of wireless communication.

This is a continuation-in-part of application Ser. No. 11/493,636, filed Jul. 27, 2006.

### BACKGROUND OF THE INVENTION

1. Field of the Invention

The present invention relates to a laptop, and more especially, to the laptop with wireless communication functions.

2. Background of the Related Art

Communication is one of fundamental demands among people. Internet access is one kind of interaction between people and a machine. With bandwidth and charge for information packets, the third Generation (3G) mobile communication provides users with a mobile phone capable of accessing the Internet.

Nowadays, the 3G mobile phone with abundant color in an enlarged screen and faster speed has been developed toward the Internet network, however, it is still viewed as a “phone”. It is very clear for customers to distinguish the mobile phone from a computer. On the other hand, the mobile PC, such as a laptop, is developed toward small size, lightweight and full wireless Internet access functions, but the functions of the small size, lightweight laptop are limited by the sizes of the existent electronic components. Furthermore, normally the laptop is added some certain functions in an external connected way or a detachable way. FIG. 1 discloses that a Printed Circuit Board (PCB) antenna 14 is connected to the peripheral port of the laptop 10 by using an external hanging-component and an external exposed transmission line 16. Although the additional functions of the laptop may be added in the foregoing ways, the usage is inconvenient because maybe the external hanging-component is forgot to carry or maybe the external exposed transmission line is pulled and dragged in using to lower the entire beauty of the laptop.

### SUMMARY OF THE INVENTION

One object of this invention is to provide a laptop with a compact shell and a wireless module built in the laptop to satisfy both the demands of easy-carry and complete functions.

One object of this invention is to provide a laptop, wherein one or more wireless antennas are fixed on the outer shell of the display and distributed within the frame-shaped interval, and one or more transmission lines are distributed along the frame-shaped interval to electrically connect the wireless antennas and the wireless module set in the base, and so as to provide the laptop with the wireless communication ability and to improve the communication quality of the external connected components.

One object of this invention is to provide a laptop, wherein the outer shell of the display is configured for both fixing and grounding one or more wireless antennas, so that the aforementioned antennas requires the less expenditure of material and fabricating cost.

One object of this invention is to provide a laptop, wherein the display can be horizontally rotated in 180 degrees by means of a hinge structure, so that people in different positions can share the display by rotating the display to have the advantage of high practicability.

Accordingly, one embodiment of the present invention provides a laptop. which includes: a base having a hinge structure on a side of the base; a wireless module set in the base; a display pivotally connected with the hinge structure, wherein the display includes: an outer shell having a metal bottom and a side wall around the metal bottom; a screen configured on the metal bottom to construct a frame-shaped interval between the screen and the side wall; and a frame piece covering the frame-shaped interval; a plurality of wireless antennas configured on the outer shell and distributed within the frame-shaped interval, wherein a portion of each the wireless antenna contacts with the metal bottom to be grounding and at least one transmission line is fixed on each wireless antenna; and the plurality of transmission lines arranged along the frame-shaped interval and through the hinge structure to electrically connect with the wireless module.

### BRIEF DESCRIPTION OF THE DRAWINGS

FIG. 1 is a three-dimensional diagram illustrating a conventional laptop;

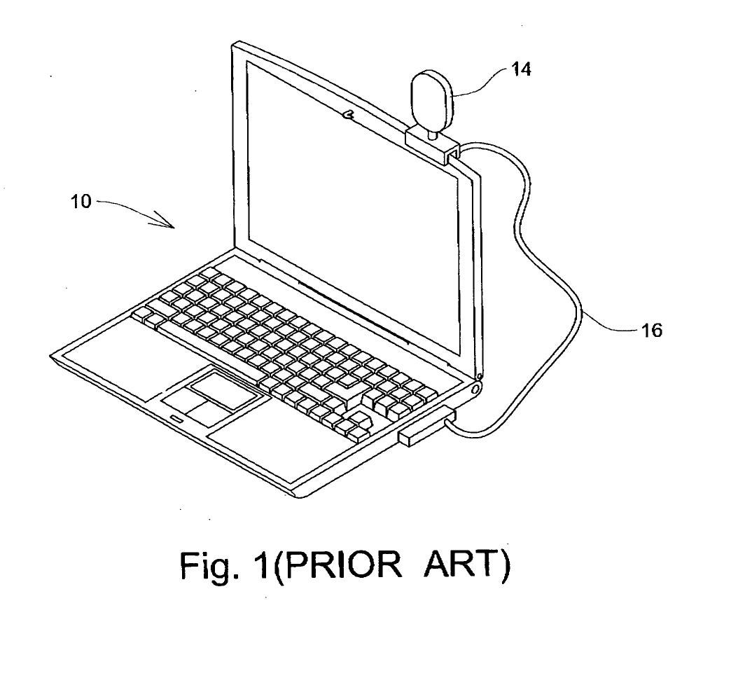

FIG. 2 is a perspective diagram illustrating the laptop in accordance with an embodiment of the present invention;

FIG. 3 is a diagram illustrating the rotating motion of the display in accordance with the embodiment of the present invention; and

FIG. 4 is a diagram illustrating the distribution of the wireless antennas and the transmission lines within the display in accordance with the embodiment of the present invention.

### DETAILED DESCRIPTION OF THE INVENTION

The technique of the present invention is illustrated in company with the drawings. In one embodiment, a laptop includes a motherboard, peripheral ports, expansion slots, a hard disk and a memory component, etc, but in order to indicate clearly the setting positions of the components of the present invention, the above-mentioned basic components inside the laptop are omitted from the drawings.

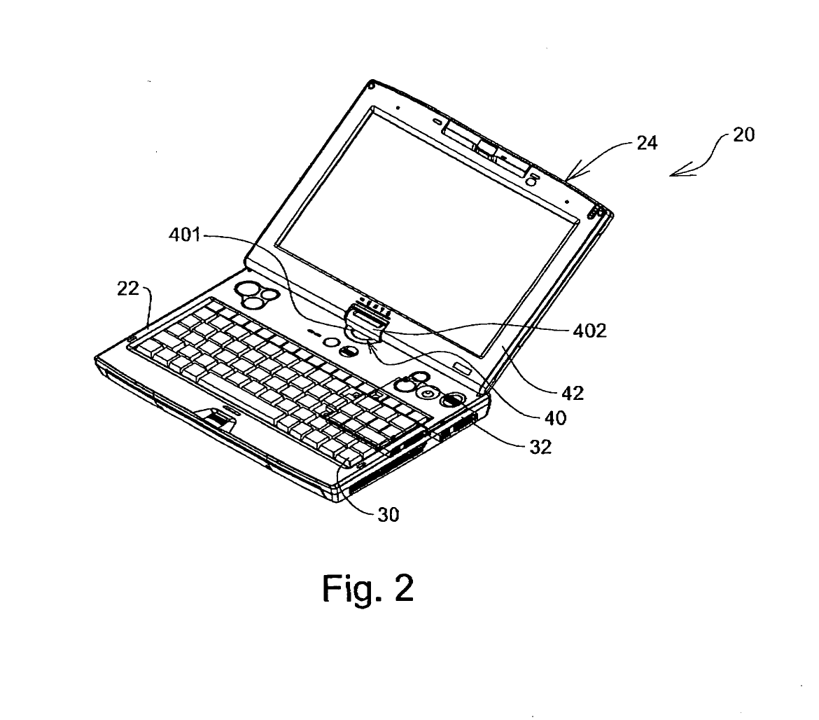

FIG. 2 is a perspective diagram illustrating the compact laptop in accordance with an embodiment of the present invention. The laptop applied in the present embodiment may include a rectangular shell with the diagonal distance smaller than or equal to 31 centimeter and the entire thickness smaller than or equal to 3.2 centimeter to fit the compact demand of the laptop. However, the present invention is not limited to it, the laptop with bigger or smaller diagonal distance or thinner thickness is in the range of the present invention.

Referring to FIG. 2, a compact laptop 20 includes a base 22 and a display 24. In the present embodiment, the motherboard and the electronic components, such as the hard disk, the memory, the peripheral ports, the battery, etc. are assembled in the base 22 to control the operation of the laptop 20, and an input apparatus 30 of the laptop 20, such as a keyboard, is configured on the surface of the base 22. According to the spirit of the present invention, a wireless module 32, such as a 3G or higher wireless network mini-PCI card is set in the base 22 or elsewhere.

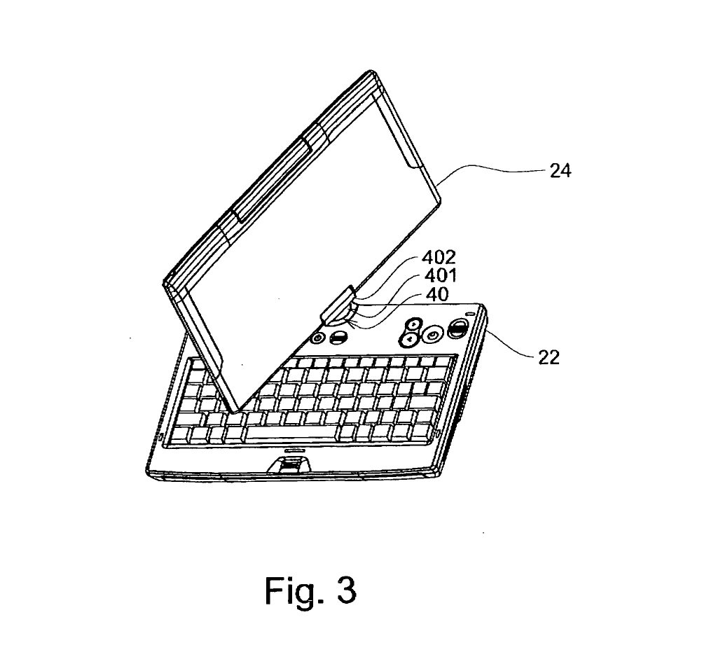

In the present invention, a hinge structure 40 including a vertical band 401 and a horizontal band 402 is configured on the rear side of the base 22. The vertical band 401 is pivotally and horizontally rotatable connected with the rear side of the base 22, and the horizontal band 402 which is used to pivotally connect with the display 24 is combined to the top of the vertical band 401. Therefore, as shown in FIG. 3, the display 24 is relative to the base 22 with the opening and closing movement by means of the horizontal band 402 of the hinge structure 40, and furthermore the display 24 can be horizontally rotated in 180 degrees by means of the vertical band 401 of the hinge structure 40.

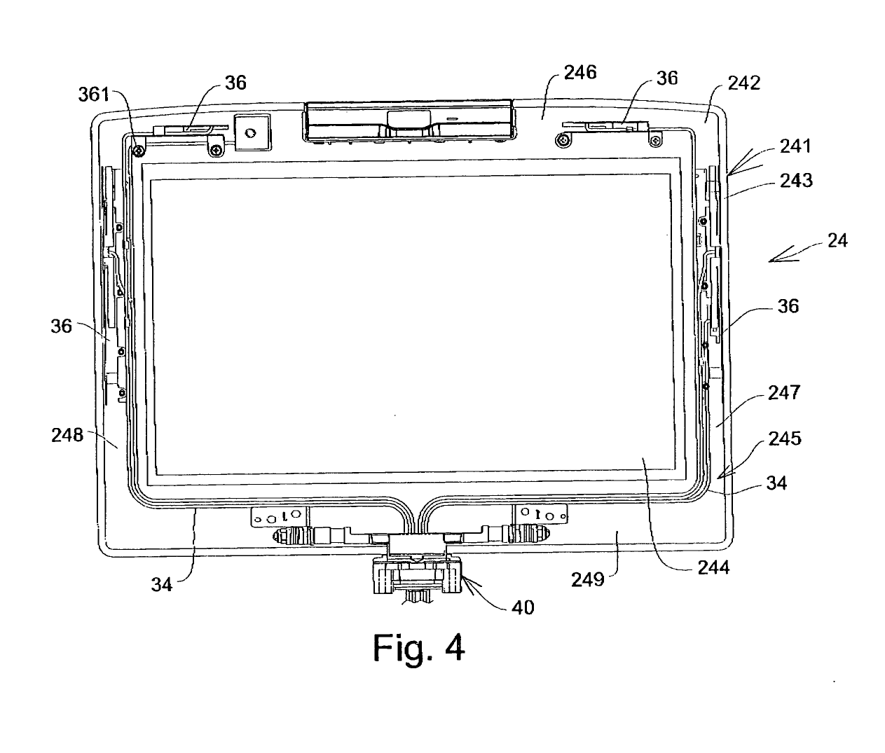

Please refer to FIG. 2 and FIG. 4, the foregoing display 24 includes an outer shell 241 having a metal bottom 242 and a side wall 243 at the outer circumference of the metal bottom 242. There exists a frame-shape interval 245 between the screen 244 and the side wall 243 because the screen 244 which is configured on the metal bottom 242 is smaller than the metal bottom 242, wherein the frame-shaped interval 245 is divided into a top interval 246, a right interval 247, a left interval 248 and a bottom interval 249, and a frame piece 42 (shown in FIG. 2) is used to cover the frame-shaped interval 245.

Continuously, as shown in FIG. 4, some kinds of the wireless antennas 36, such as the 3G wireless antennas, the Bluetooth antenna, the WLAN antenna, and the GPS antenna are fixed on the outer shell 241 by means of the screws 361 and distributed within the top interval 246, the right interval 247 and the left interval 248. Moreover, the screws are configured for grounding. Wherein, at least one portion of each wireless antenna 36 is bended to contact with the metal bottom 242 to be grounding via the screws 361. Furthermore, at least one transmission line 34 which is distributed along the frame-shaped interval 245 is used to connect each wireless antenna 36 to the wireless module 32 (shown in FIG. 2). Then, most of the wireless antennas 34 assemble and pass through the hinge structure 40 to electrically connect with the wireless module 32. Wherein, the foregoing antennas maybe extend at least four dimensional planes.

In the present invention, the outer shell of the display is not only used to fix the wireless antenna, but also to provide the grounding function needful for the wireless antenna, and so as to improve the conventional antenna setting technique, in which a bracket is required to fix on the display frame and then the antennas are screwed on the bracket. Accordingly, because the outer shell can provide both fixing function and grounding function of wireless antennas, the fabrications of the antennas have the advantages of decreasing material and reducing the fabricating cost. Bedsides, because the display can be horizontally rotated in 180 degrees by means of the hinge structure, people in different positions can share the display by rotating the display to have the advantage of high practicability.

Accordingly, the wireless module 32 and the wireless antennas 36 are built in the laptop 20, and the communication transmission lines are also distributed between the display 24 and the base 22. Users may connect to the Internet and fetch the information what they want anywhere and anytime whenever the laptop is under the service area of the wireless network. Compared with the conventional technique on the laptop 20 in an external connection way, the wireless apparatus of the present invention is built in the laptop 20 to increase the quality of the wireless communication and the users may test the wireless apparatus together with the quality test of the laptop. Furthermore, the function of accessing wireless network is achieved by carrying the laptop of the present invention without any additional component, which further increases the portable property of the laptop.

A laptop includes a base whose diagonal distance is smaller than 31 centimeter or equal to 31 centimeter; a display pivotally connected with the base, wherein the entire thickness of both the base and the display is smaller than 3.2 centimeter or equal to 3.2 centimeter; a wireless module set in the base; and a wireless antenna set in the display and electrically connected with the wireless module.

Although the present invention has been explained in relation to its preferred embodiment, it is to be understood that other modifications and variation can be made without departing the spirit and scope of the invention as hereafter claimed.

What is claimed is:

1. A laptop, comprising:
a base having a hinge structure on a side of said base;
a wireless module set in said base;
a display pivotally connected with said hinge structure, and said display comprising:
an outer shell having a metal bottom and a side wall around said metal bottom;
a screen configured on said metal bottom to construct a frame-shaped interval between said screen and said side wall; and
a frame piece covering said frame-shaped interval;
a plurality of wireless antennas configured on said outer shell and distributed within said frame-shaped interval, wherein a portion of each said wireless antenna contacts with said metal bottom is to be grounding and at least one transmission line is fixed on each said wireless antenna; and
said plurality of transmission lines arranged along said frame-shaped interval and through said hinge structure to electrically connect with said wireless module.

2. The laptop according to claim 1, wherein said hinge structure comprises:
a vertical band pivotally and horizontally rotatable connected with said side of said base; and
a horizontal band combined with a top of said vertical band, wherein said horizontal band is used to pivotally connected with said display.

3. The laptop according to claim 1, wherein said frame-shaped interval is divided into a top interval, a right interval, a left interval and a bottom interval, and said plurality wireless antennas are distributed within said top interval, said right interval and said left interval.

4. The laptop according to claim 1, wherein said wireless antennas are fixing on said outer shell by screwing.

5. The laptop according to claim 1, wherein each said wireless antenna extends at least four dimensional planes.

6. The laptop according to claim 1, wherein said wireless antennas comprises a 3G wireless antenna, a blue tooth antenna, a WLAN antenna, and a GPS antenna.

7. The laptop according to claim 1, wherein one diagonal distance of said base is smaller than 31 centimeter or equal to 31 centimeter.

8. The laptop according to claim 1, wherein an entire thickness of both said base and said display is smaller than 3.2 centimeter or equal to 3.2 centimeter.

9. A laptop, comprising:
a base having a hinge structure on a side of said base, wherein one diagonal distance of said base is smaller than 31 centimeter or equal to 31 centimeter;
a wireless module set in said base;
a display pivotally connected with said hinge structure, wherein one entire thickness of both said base and said display is smaller than 3.2 centimeter or equal to 3.2 centimeter, and said display comprising:
an outer shell having a metal bottom and a side wall around said metal bottom;
a screen configured on said metal bottom to construct a frame-shaped interval between said screen and said side wall; and
a frame piece covering said frame-shaped interval;
a plurality of wireless antennas configured on said outer shell and distributed within said frame-shaped interval, wherein a portion of each said wireless antenna contacts with said metal bottom to be grounding and at least one transmission line is fixed on each said wireless antenna; and
said plurality of transmission lines arranged along said frame-shaped interval and through said hinge structure to electrically connect with said wireless module.

10. The laptop according to claim 9, wherein said hinge structure comprises:
a vertical band pivotally and horizontally rotatable connected with said side of said base; and
a horizontal band combined with a top of said vertical band, wherein said horizontal band is used to pivotally connected with said display.

11. The laptop according to claim 9, wherein said frame-shaped interval is divided into a top interval, a right interval, a left interval and a bottom interval, and said plurality wireless antennas are distributed within said top interval, said right interval and said left interval.

12. The laptop according to claim 9, wherein said wireless antennas are fixing on said outer shell by screwing.

13. The laptop according to claim 9, wherein each said wireless antenna extends at least four dimensional planes.

14. The laptop according to claim 9, wherein said wireless antennas comprises a 3G wireless antenna, a blue tooth antenna, a WLAN antenna, and a GPS antenna.
